(19) United States
(12) Patent Application Publication
(10) Pub. No.: US 2025/0174577 A1
(43) Pub. Date: May 29, 2025

(54) DISPLAY DEVICE AND METHOD OF MANUFACTURING DISPLAY DEVICE

(71) Applicant: Samsung Display Co., LTD., Yongin-si (KR)

(72) Inventors: JUNYOUNG LEE, Yongin-si (KR); DONGHWAN KIM, Yongin-si (KR); YOUNGDO KIM, Yongin-si (KR); JEONGWEON SEO, Yongin-si (KR); JUNWOO YOU, Yongin-si (KR); CHANGMOO LEE, Yongin-si (KR)

(21) Appl. No.: 18/957,826

(22) Filed: Nov. 24, 2024

(30) Foreign Application Priority Data
Nov. 27, 2023 (KR) 10-2023-0167229

(51) Int. Cl. H01L 23/00; H01L 23/373

(52) U.S. Cl. CPC H01L 23/562; H01L 23/3737

(57) ABSTRACT

An electronic device includes a display panel having a display region and a non-display region surrounding at least a portion of the display region, and a protective layer disposed under the display panel. The protective layer includes a first protective portion overlapping the display region and having a first density, and a second protective portion overlapping the non-display region and having a second density. The first density is greater than the second density.

This application claims priority to Korean Patent Application No. 10-2023-0167229, filed on Nov. 27, 2023, and all the benefits accruing therefrom under 35 U.S.C. § 119, the content of which in its entirety is herein incorporated by reference.

### BACKGROUND

### (1) Field

The disclosure herein relates to an electronic device and a method of manufacturing the electronic device, and more particularly, to an electronic device with improved reliability, and a method of manufacturing the electronic device.

### (2) Description of the Related Art

Electronic devices such as smart phones, digital cameras, notebook computers, car navigation systems, and smart televisions provide an image to a user through a display screen.

A electronic device may include a display panel for providing image information, and a protective layer for protecting the display panel from the outside. The protective layer may effectively prevent a deformation of the display panel due to an external impact, effectively dissipate heat generated in the display panel, and protect the display panel from the outside. The protective layer may have a structure, in which a plurality of functional layers are stacked, in order to provide various functions for protecting the display panel.

Recently, studies are being conducted on an electronic device in which a single-layered protective layer having various functions for protecting a display panel all-in-one is applied and a method of manufacturing the electronic device.

### SUMMARY

The disclosure provides an electronic device with improved reliability, and a method of manufacturing an electronic device.

An embodiment of the invention provides an electronic device including: a display panel having a display region and a non-display region surrounding at least a portion of the display region; and a protective layer disposed under the display panel, where the protective layer includes a first protective portion overlapping the display region and having a first density, and a second protective portion overlapping the non-display region and having a second density, and the first density is greater than the second density.

In an embodiment, a thermal conductivity of the first protective portion may be different from a thermal conductivity of the second protective portion.

In an embodiment, the thermal conductivity of the first protective portion may be in a range of about 70 Watts per meter Kelvin (W/mK) to about 200 W/mK.

In an embodiment, the first protective portion may include a first base resin, and a first filler dispersed in the first base resin, and the second protective portion may include a second base resin, and a second filler dispersed in the second base resin.

In an embodiment, a weight ratio of the first filler to a total weight of the first protective portion may be greater than a weight ratio of the second filler to a total weight of the second protective portion.

In an embodiment, materials of the first base resin and the second base resin may be the same as each other, and materials of the first filler and the second filler may be the same as each other.

In an embodiment, an average diameter of each of the first filler and the second filler may be in a range of about 5 micrometers (μm) to about 100 μm.

In an embodiment, the protective layer may be disposed directly on a lower surface of the display panel.

In an embodiment, a thickness of the first protective portion and a thickness of the second protective portion may each be in a range of about 50 μm to about 300 μm.

In an embodiment, a thickness of the first protective portion and a thickness of the second protective portion may be substantially the same as each other.

In an embodiment of the invention, a method of manufacturing an electronic device, the method including: preparing a display panel having a display region and a non-display region surrounding the display region, and a mask disposed on a first lower surface of the display panel; providing an ink on the first lower surface; forming an ink layer by pressurizing the ink with a first squeegee to apply the ink to the first lower surface in a way such that the ink layer overlaps the display region and the non-display region; disposing a stamp while being spaced at a distance in one direction with respect to the first lower surface, in a way such that the stamp overlaps the display region and does not overlap the non-display region; forming a preliminary protective layer by pressurizing a portion of the ink layer overlapping the display region with the stamp in an opposite direction of the one direction; and forming a protective layer by pressurizing and flattening, with a second squeegee, a top surface of the preliminary protective layer which overlaps the display region and the non-display region.

In an embodiment, the ink layer may include a first ink part overlapping the display region and a second ink part overlapping the non-display region, and a density of the first ink part may be substantially the same as a density of the second ink part.

In an embodiment, the preliminary protective layer may include a first preliminary protective portion overlapping the display region and a second preliminary protective portion overlapping the non-display region, and a thickness of the first preliminary protective portion may be less than a thickness of the second preliminary protective portion.

In an embodiment, the protective layer may include a first protective portion overlapping the display region and a second protective portion overlapping the non-display region, and a first density of the first protective portion may be greater than a second density of the second protective portion.

In an embodiment, in the pressurizing the ink with the first squeegee to apply the ink to the first lower surface, the first squeegee may move in a first direction, and a first length of the first squeegee in a second direction crossing the first direction on a plane may be greater than a second length of the second squeegee in the second direction.

In an embodiment, the first length may be greater than a third length of the display panel in the second direction, and the second length may be substantially the same as the third length.

In an embodiment, the ink may be in contact with at least a portion of a top surface of the mask.

In an embodiment, the ink may include a curable resin, and the forming the preliminary protective layer may include thermally curing the curable resin included in the ink.

In an embodiment, the preliminary protective layer may include a first preliminary protective portion overlapping the display region and a second preliminary protective portion overlapping the non-display region, and the forming the preliminary protective layer may include thermally curing the first preliminary protective portion.

In an embodiment, in the forming the preliminary protective layer, one surface of the stamp may be in contact with one surface of the ink layer, and the one surface of the stamp may have a temperature of about 100° C. or higher.

### BRIEF DESCRIPTION OF THE DRAWINGS

The above and other features of embodiments of the invention will become more apparent by describing in further detail embodiments thereof with reference to the accompanying drawings, in which:

FIG. 1 is a perspective view of an electronic device according to an embodiment of the invention;

FIG. 2 is an exploded perspective view of an electronic device according to an embodiment of the invention;

FIG. 3 is a cross-sectional view illustrating a partial configuration of an electronic device according to an embodiment of the invention;

FIG. 4 is a cross-sectional view of a display panel according to an embodiment;

FIG. 5 is a cross-sectional view of a portion of an electronic device according to an embodiment of the invention;

FIG. 6 is an enlarged cross-sectional view of a portion of an electronic device according to an embodiment of the invention;

FIG. 7 is a flowchart illustrating a method of manufacturing an electronic device according to an embodiment of the invention;

FIGS. 8A, 8C, 8D, 8E, and 8G are cross-sectional views illustrating some processes of a method of manufacturing an electronic device according to an embodiment of the invention; and

FIGS. 8B and 8F are plan views illustrating some processes of a method of manufacturing an electronic device according to an embodiment of the invention.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

In this specification, it will be understood that when a component (or a region, layer, portion, etc.) is referred to as being “on”, “connected to” or “coupled to” another component, it can be directly on/connected/coupled to the other component or intervening component may be present.

Meanwhile, in this specification, when an element is referred to as being “directly on,” “directly connected to” or “directly coupled to” another layer, film, region, substrate, or the like, there are no intervening layers, films, regions, substrates, or the like present. For example, the wording, “being directly disposed” means that two layers or two members are disposed without using an additional member such as an adhesive member, or the like therebetween.

Like numerals or symbols refer to like elements throughout. In addition, with regard to the drawings, the thickness and the ratio and the dimension of the element are exaggerated for effective description of the technical contents.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

In addition, spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which the disclosure belongs. In addition, it will be further understood that terms, such as those defined in commonly used dictionaries, should be interpreted as having a meaning that is consistent with their meaning in the context of the relevant art and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the invention will be described with reference to the accompanying drawings.

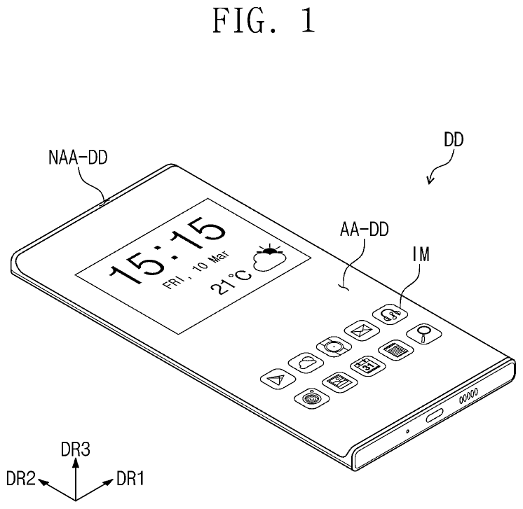

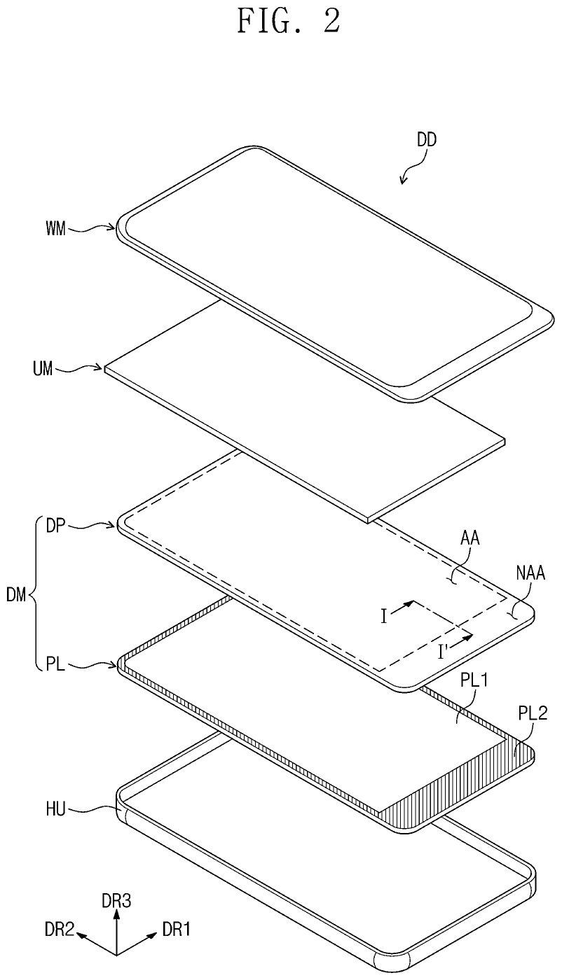

FIG. 1 is a perspective view of an electronic device DD according to an embodiment of the invention. FIG. 2 is an exploded perspective view of an electronic device DD according to an embodiment of the invention.

The electronic device DD according to an embodiment may be activated in response to an electrical signal. In an embodiment, for example, the electronic device DD may be a mobile phone, a tablet computer, a car navigation system, a game console or a wearable device, but is not limited thereto. FIG. 1 illustrates an embodiment where the electronic device DD is a mobile phone as an example.

The electronic device DD may display an image IM through an active region AA-DD. The active region AA-DD may include a flat surface defined by a first direction DR1 and a second direction DR2. The active region AA-DD may further include a curved surface which is bent from at least one side of the flat surface defined by the first direction DR1 and the second direction DR2. FIG. 1 illustrates an embodiment where the electronic device DD include two curved surfaces which are respectively bent from both sides of the flat surface defined by the first direction DR1 and the second direction DR2. However, a shape of the active region AA-DD is not limited thereto. In another embodiment, for example, the active region AA-DD may include the flat surface only, or the active region AA-DD may further include four curved surfaces which are respectively bent from at least two or more, for example, four sides of the flat surface.

In FIG. 1 and subsequent drawings, first to third directions DR1 to DR3 are illustrated, and the directions indicated by the first direction DR1, the second direction DR2, and the third direction DR3 illustrated in this specification may have a relative concept and may thus be changed to other directions.

In this specification, the first direction DR1 and the second direction DR2 may be perpendicular to each other, and the third direction may be a normal direction of a plane defined by the first direction DR1 and the second direction DR2. In this specification, the wording “on a plane” or “in a plan view” may mean “when viewed on the plane defined by the first direction DR1 and the second direction DR2” or “when viewed in a thickness direction”, and the thickness direction may mean the third direction DR3 which is the normal direction of the plane defined by the first direction DR1 and the second direction DR2.

The electronic device DD may include the active region AA-DD and a peripheral region NAA-DD adjacent to the active region AA-DD. The active region AA-DD may correspond to a display region AA of a display panel DP, to be described later, and the peripheral region NAA-DD may correspond to a non-display region NAA of the display panel DP.

The peripheral region NAA-DD may be a region which is disposed on the outside of the active region AA-DD and surrounds the active region AA-DD while blocking a light signal. In an embodiment, the peripheral region NAA-DD may be disposed not on a front surface but on a side surface of the electronic device DD. In an embodiment, the peripheral region NAA-DD may be omitted.

The electronic device DD according to an embodiment may include a window WM, an upper member UM, a display module DM, and a housing HU.

The electronic device DD according to an embodiment may include the window WM disposed on the display panel DP. The window WM may provide or define an outer surface of the electronic device DD. The window WM may cover a front surface of the display panel DP, and may protect the display panel DP from an external impact and a scratch. The window WM may be coupled to the upper member UM through an adhesive layer.

The window WM may include an optically transparent insulating material. In an embodiment, for example, the window WM may include a glass film or a synthetic resin film as a base film. The window WM may have a single- or multi-layered structure. In an embodiment, for example, the window WM may include a plurality of plastic films which are coupled by an adhesive, or may include a glass film and a plastic film which are coupled by an adhesive. The window WM may further include a functional layer such as an anti-fingerprint layer, a phase control layer, and a hard coating layer which are disposed on a transparent film.

In the electronic device DD according to an embodiment, the upper member UM may be disposed under the window WM and on the display module DM, that is, between the window WM and the display module DM. The upper member UM may include an anti-reflection layer and an input detection sensor. The anti-reflection layer may reduce external light reflectance. The input detection sensor may sense an external input of a user. The upper member UM may further include an adhesive layer for coupling the anti-reflection layer and the input detection sensor.

In the electronic device DD according to an embodiment, the display module DM may be disposed under the upper member UM. The display module DM may include the display panel DP and a protective layer PL. The display panel DP may be disposed under the upper member UM, and the protective layer PL may be disposed under the display panel DP.

The display panel DP may include a display region AA in which an image IM is displayed and a non-display region NAA adjacent to the display region AA. That is, a front surface of the display panel DP may include the display region AA and the non-display region NAA. The display region AA may be activated in response to an electrical signal, and thus may generate the image IM which is displayed in the active region AA-DD of the electronic device DD.

The non-display region NAA may be adjacent to the display region AA. The non-display region NAA may surround the display region AA. A driving circuit or a driving wire for operating the display region AA, various signal lines or pads for providing an electrical signal to the display region AA, an electronic element, or the like may be disposed in the non-display region NAA.

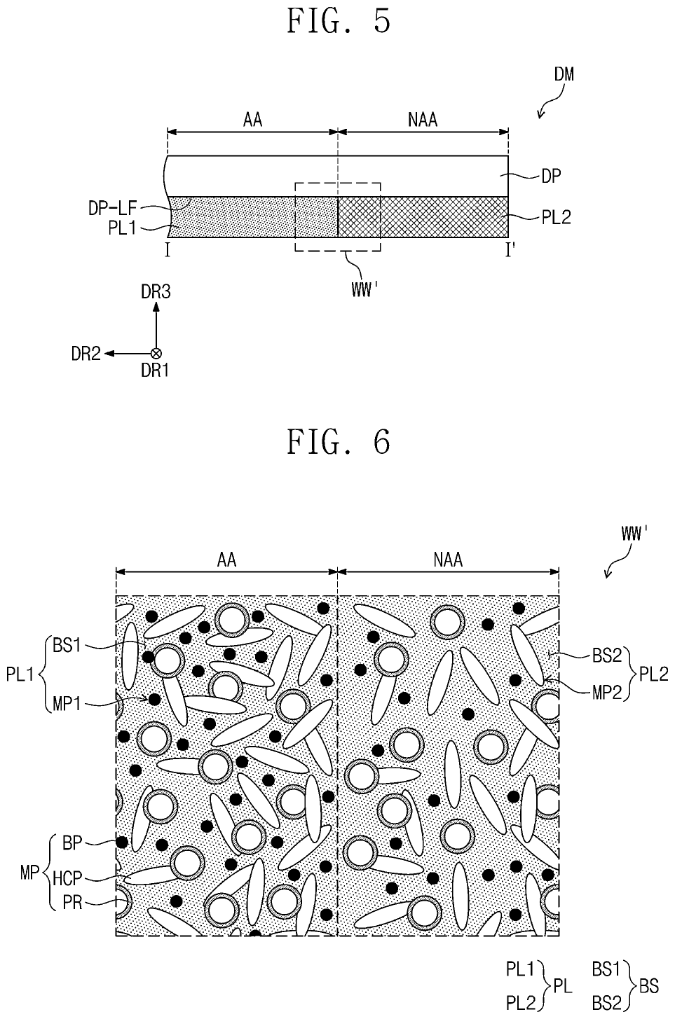

The display panel DP may include a light emitting element layer DP-ED (see FIG. 4) including an organic light emitting element, a quantum dot light emitting element, a micro light emitting diode (LED) light emitting element, a nano LED light emitting element, or the like. The light emitting element layer DP-ED (see FIG. 4) may be a component for substantially generating an image.

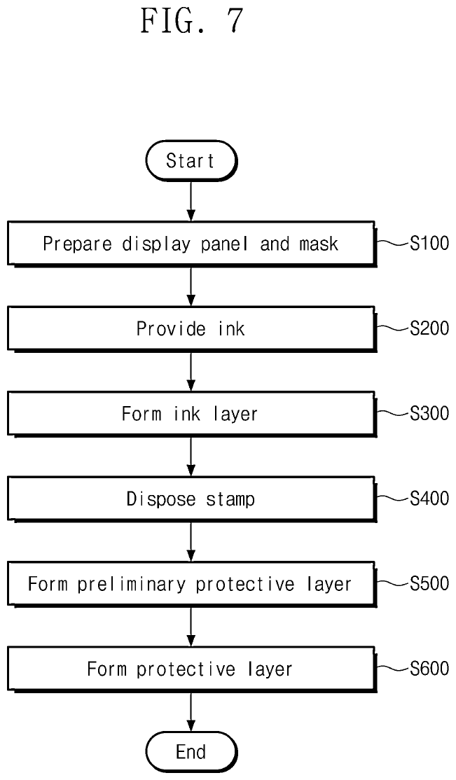

The protective layer PL may be disposed under the display panel DP. The protective layer PL may be a member which supports the display panel DP, absorbs a shock applied to the display panel DP, and performs a heat-dissipating function for dissipating heat generated in components, which are disposed under the display panel DP, for example, electronic modules (not illustrated) such as a sensor, a camera, or the like. The protective layer PL may include a first protective portion PL1 and a second protective portion PL2. The protective layer PL will be described later in detail with reference to FIG. 5 and subsequent drawings.

Although not illustrated, in an embodiment, the electronic device DD may include a flexible printed circuit board electrically connected to the display panel DP and a main circuit board connected to the flexible printed circuit board. The flexible printed circuit board may be disposed on the non-display region NAA of the display panel DP and coupled to the display panel DP. The flexible printed circuit board may be connected to the main circuit board. A region adjacent to the flexible printed circuit board of the non-display region NAA in the display panel DP may be provided as a bending region. The bending region may be bent with respect to a bending axis which is parallel to the first direction DR1. The flexible printed circuit board may overlap one portion of the display panel DP on a plane, due to bending of the bending region.

The electronic device DD according to an embodiment may include the housing HU disposed under the display panel DP. An electronic module (not illustrated), the display panel DP, or the like may be accommodated in the housing HU. In the electronic device DD according to an embodiment, the window WM and the housing HU may be coupled to each other to form an exterior of the electronic device DD.

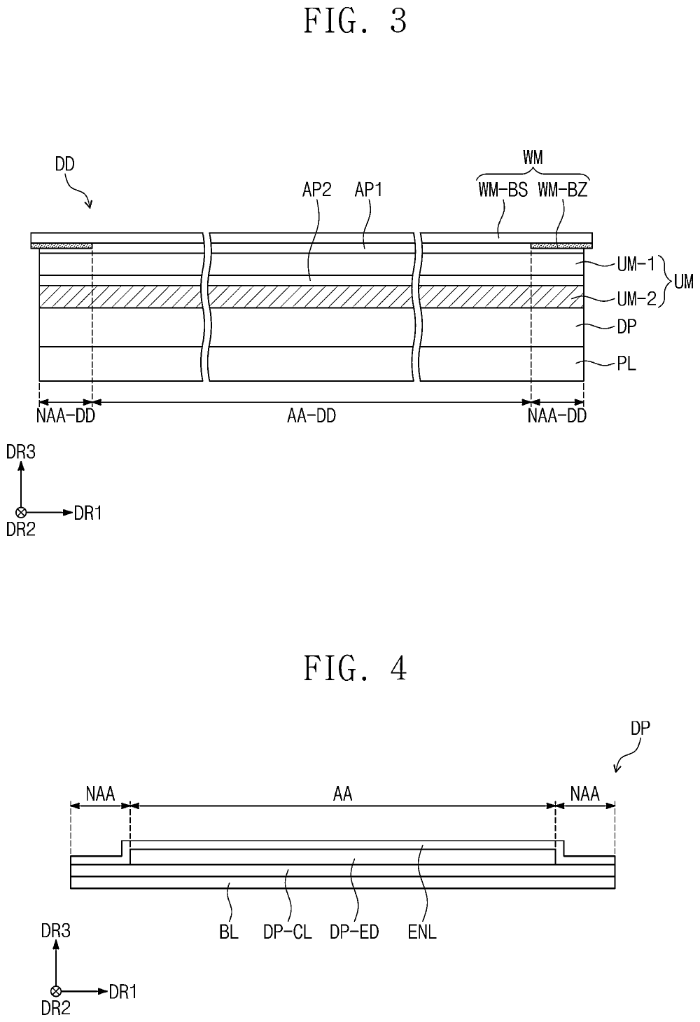

FIG. 3 is a cross-sectional view illustrating a partial configuration of an electronic device DD according to an embodiment of the invention.

Referring to FIG. 3, the electronic device DD according to an embodiment of the invention may include a window WM, an upper member UM, a display panel DP, and a protective layer PL. The electronic device DD may include a front surface and a rear surface, the front surface of the electronic device DD may be defined by the window WM, and the rear surface of the electronic device DD may be defined by the protective layer PL.

In an embodiment, the window WM may cover a front surface of the display panel DP. The window WM may include a base substrate WM-BS and a bezel pattern WM-BZ. The base substrate WM-BS may include a transparent base layer such as a glass substrate or a transparent film. The bezel pattern WM-BZ may have a multi-layered structure. The multi-layered structure may include a colored color-layer and a light shielding layer of black color. The colored color-layer and the light shielding layer of black color may be formed through a deposition, printing, or coating process. In another embodiment, the bezel pattern WM-BZ may be omitted from the window WM, and may be formed on the upper member UM, not on the base substrate WM-BS.

In an embodiment, the upper member UM may include an anti-reflection layer UM-1 and an input sensor UM-2. In an embodiment, as illustrated in FIG. 3, the window WM and the anti-reflection layer UM-1 may be coupled to each other through a first adhesive layer AP1, and the input sensor UM-2 may be coupled thereto through a second adhesive layer AP2. In another embodiment, at least one selected from the first adhesive layer AP1 and the second adhesive layer AP2 may be omitted. In an embodiment, for example, the second adhesive layer AP2 may be omitted, and the anti-reflection layer UM-1 may be disposed directly on the input sensor UM-2.

The anti-reflection layer UM-1 may reduce external light reflectance. The anti-reflection layer UM-1 may include a phase retarder and/or a polarizer. The anti-reflection layer UM-1 may include a polarizing film or color filters. The color filters may have a predetermined arrangement. The arrangement of the color filters may be determined in accordance with colors of light emitted from pixels included in the display panel DP. The anti-reflection layer UM-1 may further include a dividing layer adjacent to the color filters.

The input sensor UM-2 may include a plurality of sensing electrodes (not illustrated) for sensing an external input, trace lines (not illustrated) connected to the plurality of the sensing electrodes, and an inorganic layer and/or an organic layer for insulating/protecting the plurality of the sensing electrodes or the trace lines. The input sensor UM-2 may be a capacitive sensor, but is not particularly limited.

In an embodiment of a method of manufacturing the display panel DP, the input sensor UM-2 may be formed directly on a thin-film encapsulation layer through a continuous process. However, an embodiment of the invention is not limited thereto, and the input sensor UM-2 may be manufactured as a separated panel from the display panel DP and thus attached to the display panel DP by an adhesive layer.

The protective layer PL may be disposed under the display panel DP. The protective layer PL may be a member which supports the display panel DP, and performs a heat-dissipating function for dissipating heat generated in the display panel DP. The protective layer PL will be described in detail with reference to FIG. 5 and subsequent drawings.

FIG. 4 is a cross-sectional view of a display panel DP according to an embodiment.

In an embodiment, the display panel DP may include a base layer BL, a circuit layer DP-CL disposed on the base layer BL, a light emitting element layer DP-ED, and an encapsulation layer ENL.

The base layer BL may include a plastic substrate, a glass substrate, a metal substrate, an organic/inorganic composite material substrate, or the like. In an embodiment, for example, the base layer BL may include at least one polyimide layer. The aforementioned protective layer PL (see FIG. 3) may be disposed under the base layer BL.

The circuit layer DP-CL may include at least one insulating layer, semiconductor patterns, and conductive patterns. The insulating layer may include at least one inorganic layer and at least one organic layer. The semiconductor patterns and the conductive patterns may constitute or define signal lines, a pixel driving circuit, and a scan driving circuit. In addition, the circuit layer DP-CL may include a backside metal layer.

The light emitting element layer DP-ED may include a display element, for example, a light emitting element. In an embodiment, for example, the light emitting element may be an organic light emitting element, a quantum dot light emitting element, a micro LED light emitting element, or a nano LED light emitting element. The light emitting element layer DP-ED may further include an organic layer such as a pixel-defining film.

The light emitting element layer DP-ED may be disposed in a display region AA. Since a non-display region NAA is disposed on the outside of the display region AA and surrounds the display region AA, the light emitting element may not be disposed in the non-display region NAA.

The encapsulation layer ENL may be disposed on the light emitting element layer DP-ED and may cover the light emitting element layer DP-ED. The encapsulation layer ENL may be disposed on the circuit layer DP-CL for sealing the light emitting element layer DP-ED. The encapsulation layer ENL may be a thin-film encapsulation layer including a plurality of organic thin-films and inorganic thin-films. The encapsulation layer ENL may include a thin-film encapsulation layer having a stacked structure of inorganic layer/organic layer/inorganic layer. The stacked structure of the encapsulation layer ENL is not particularly limited.

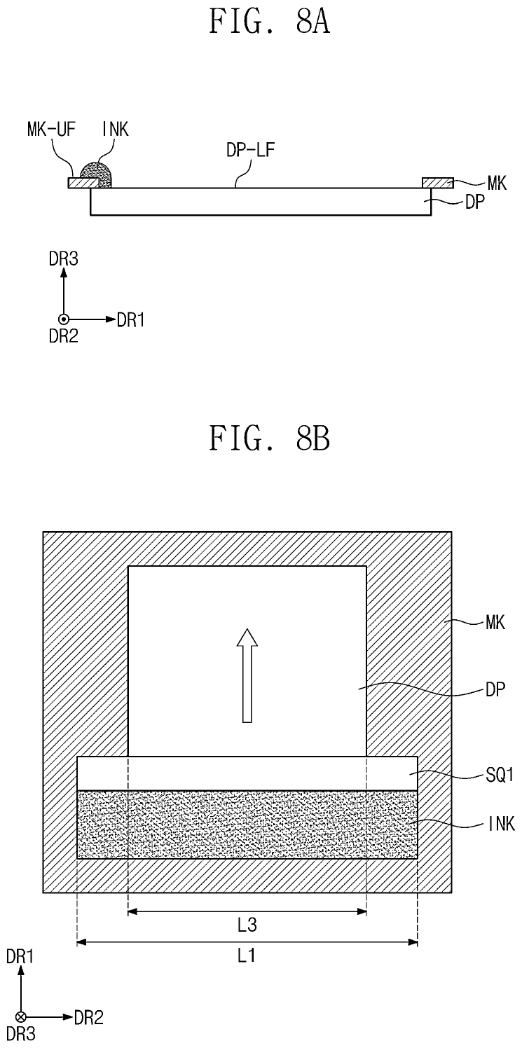

FIG. 5 is a cross-sectional view of a portion of a display module according to an embodiment of the invention. Particularly, FIG. 5 illustrates a cross-section taken along line I-I′ illustrated in FIG. 2. FIG. 6 is an enlarged cross-sectional view of a portion of a display module according to an embodiment of the invention. Particularly, FIG. 6 is an enlarged cross-sectional view illustrating a region WW′ illustrated in FIG. 5. FIG. 6 is a cross-sectional view illustrating a protective layer PL, in detail, according to an embodiment of the invention.

Referring to FIGS. 5 and 6, a display module DM according to an embodiment of the invention may include a display panel DP and a protective layer PL.

The protective layer PL may be disposed under the display panel DP. The protective layer PL may be disposed directly under the display panel DP. The protective layer PL may be in contact with a lower surface DP-LF of the display panel DP. No adhesive member may be disposed between the protective layer PL and the display panel DP. The protective layer PL may be provided in the form of a single layer on the lower surface DP-LF of the display panel DP according to an embodiment. The protective layer PL may be a member which supports the display panel DP, absorbs impacts applied to the display panel DP, and performs a heat-dissipating function for dissipating heat generated in components, for example, an electronic module (not illustrated), or the like that are disposed under the display panel DP. Since the protective layer PL, in the form of a single layer, simultaneously performs a shock-absorbing function, a heat-dissipating function, and the like, a thickness of the electronic device DD may be reduced and components thereof may be simplified, and thus process efficiency may be increased in a manufacturing processes of the electronic device DD according to an embodiment.

The protective layer PL may include a base resin BS. The base resin BS may include at least one selected from an acrylate-based resin, a urethane-based resin, a fluorine-based resin, an epoxy-based resin, a polyester-based resin, a polyamide-based resin, and a silicone-based resin. The base resin BS may include a curable resin. In an embodiment, for example, the base resin BS may include a thermosetting resin or a photocurable resin.

In an embodiment, the protective layer PL may include a filler MP. The protective layer PL may include a plurality of fillers MP dispersed in the base resin BS. In such an embodiment where the filler MP is included in the protective layer PL, the protective layer PL may perform multiple functions within the electronic device. In an embodiment, the filler MP may include a shielding material BP, a heat-dissipating material HCP, and a supporting material PR. The filler MP may be used by mixing two or more substances having different types or sizes from each other. Since the filler MP includes the shielding material BP, the protective layer PL may have an electromagnetic shielding property. Since the filler MP includes the heat-dissipating material HCP, the protective layer PL may perform a heat-dissipating function for dissipating heat generated in the display panel DP, and the like. The heat-dissipating material HCP may include at least one selected from, for example, a thermally conductive metal, a carbon-based heat-dissipating material, and a thermally conductive polymer. Since the filler MP includes the supporting material PR, the protective layer PL may have an improved property of protecting the display panel DP, and the like from physical impacts applied from the outside of the display panel DP.

FIG. 6 illustrates an embodiment where the filler MP includes the shielding material BP, the heat-dissipating material HCP, and the supporting material PR, but an embodiment of the invention is not limited thereto. The protective layer PL may additionally perform other functions within the electronic device DD (see FIG. 3) depending on a material included in the protective layer PL, a thickness of the protective layer PL, a component included in the electronic device DD (see FIG. 3), or the like. In an embodiment, for example, the filler MP may further include a light-shielding material, and the protective layer PL may further perform a light-shielding function for blocking light emitted from the display panel DP.

An average diameter of the filler MP may be in a range of about 5 micrometers (μm) to about 300 μm. In an embodiment, for example, average diameters of the shielding material BP, the heat-dissipating material HCP, and the supporting material PR may each be about 5 μm to about 300 μm. The filler MP may have a substantial monodisperse size distribution or a polydisperse distribution obtained by mixing a plurality of particles having a monodisperse distribution. When the average diameter of the filler MP is less than about 5 μm, it may become difficult to achieve the shielding, heat-dissipating, or supporting properties of the protective layer PL; and when the average diameter of the filler MP is greater than about 300 μm, it may become difficult to secure uniform thin-film properties due to a lowering of the dispersing property of the filler MP in the protective layer PL. FIG. 6 merely illustrates an embodiment where the filler MP includes the shielding material BP, the heat-dissipating material HCP, and the supporting material PR, and the average diameter and the cross-sectional shape of each of the plurality of fillers MP, e.g., an average diameter and a cross-sectional shape of each of the shielding material BP, the heat-dissipating material HCP, and the supporting material PR, are not limited to those illustrated in FIG. 6, and the fillers MP may have various values or may be prepared in various shapes, as needed.

In an embodiment, the filler MP may be included in an amount of about 90 weight precent (wt %) or less with respect to a total weight of the protective layer PL. In an embodiment, for example, the filler MP may be included in an amount in a range of about 50 wt % to about 90 wt % with respect to the total weight of the protective layer PL. When the amount of the filler MP is less than about 90 wt %, the heat-dissipating property of the protective layer PL may decrease. In addition, when the amount of the filler MP is greater than about 50 wt %, the shock-absorbing property of the protective layer PL may excessively deteriorate and the shock-absorbing property of the entire protective layer PL may deteriorate, resulting in the occurrence of a defect of the display panel DP being damaged due to an external impact.

The protective layer PL may include a first protective portion PL1 and a second protective portion PL2. The first protective portion PL1 may correspond to a display region AA of the display panel DP. The second protective portion PL2 may correspond to a non-display region NAA of the display panel DP. The first protective portion PL1 may overlap the display region AA on a plane or in the third direction DR3. The first protective portion PL1 may be disposed on the lower surface DP-LF of the display panel DP to overlap the display region AA. The second protective portion PL2 may overlap the non-display region NAA on a plane or in the third direction DR3. The second protective portion PL2 may be disposed on the lower surface DP-LF of the display panel DP to overlap the non-display region NAA.

The first protective portion PL1 may include a first base resin BS1 and a first filler MP1, and the second protective portion PL2 may include a second base resin BS2 and a second filler MP2. Here, each of the first base resin BS1 and the second base resin BS2, is substantially the same as the base resin BS described above and each of the first filler MP1 and the second filler MP2 may be substantially the same as the filler MP described above. In an embodiment, the first base resin BS1 and the second base resin BS2 may include a same material as each other, and the first filler MP1 and the second filler MP2 may include a same material as each other.

The first protective portion PL1 may have a first density, and the second protective portion PL2 may have a second density less than the first density. That is, the first density of the first protective portion PL1 may be greater than the second density of the second protective portion PL2. A weight ratio of the first filler MP1 to a total weight of the first protective portion PL1 may be relatively greater than a weight ratio of the second filler MP2 to a total weight of the second protective portion PL2. A degree of concentration of the first filler MP1 in the first protective portion PL1 may be greater than a degree of concentration of the second filler MP2 in the second protective portion PL2.

A thickness of the first protective portion PL1 may be substantially the same as a thickness of the second protective portion PL2. The first protective portion PL1 and the second protective portion PL2 may each have a thickness in a range of about 50 μm to about 300 μm. In an embodiment, for example, the first protective portion PL1 and the second protective portion PL2 may each have a thickness in a range of about 100 μm to about 200 μm. In this specification, the wording “substantially the same” may include not only a case in which the thicknesses, etc., of components are physically and completely identical, but also a case in which there is a difference as much as a tolerance range that occurs during the process, despite the same design.

A thermal conductivity of the first protective portion PL1 may be greater than a thermal conductivity of the second protective portion PL2. In an embodiment, heat generated in the display region AA of the display panel DP may be greater than heat generated in the non-display region NAA of the display panel DP, and a heat-dissipating function of the first protective portion PL1 corresponding to the display region AA may be higher in performance than a heat-dissipating function of the second protective portion PL2 corresponding to the non-display region NAA. The thermal conductivity of the first protective portion PL1 may be about 70 Watts per meter Kelvin (W/mK) or greater. In an embodiment, for example, the thermal conductivity of the first protective portion PL1 may be in a range of about 70 W/mK to about 200 W/mK.

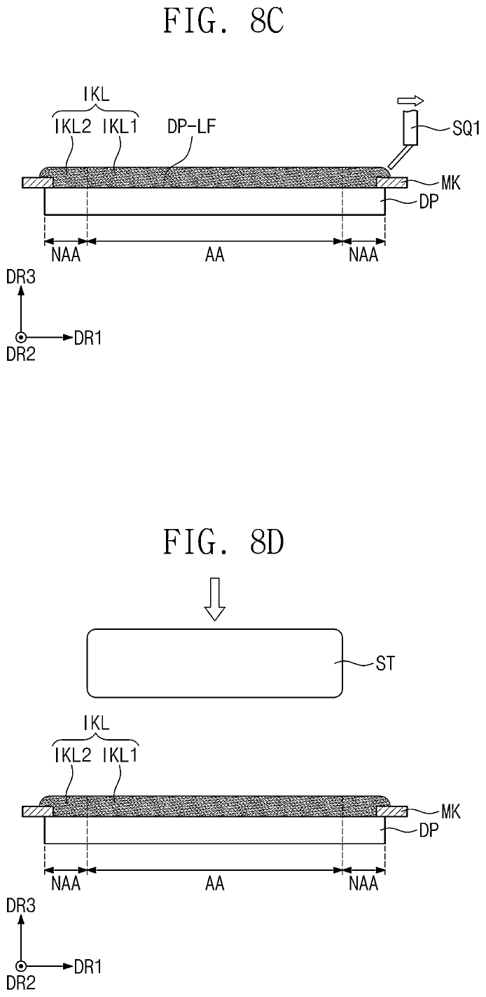

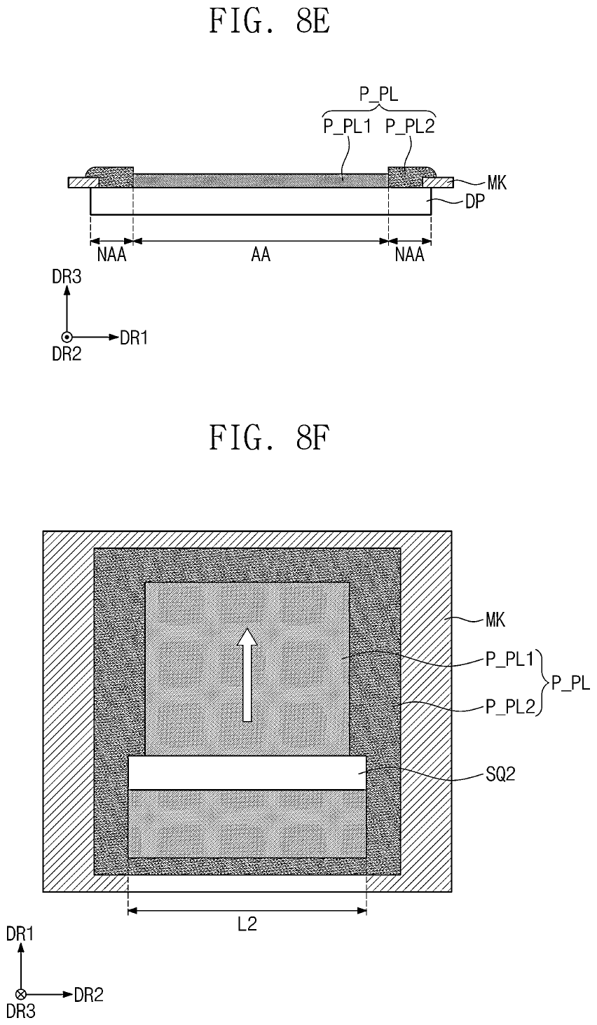

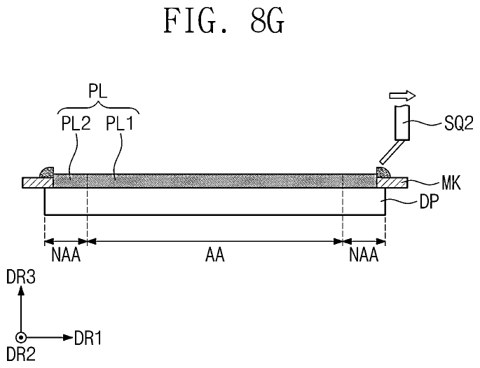

FIG. 7 is a flowchart illustrating a method of manufacturing an electronic device according to an embodiment of the invention. FIGS. 8A, 8C, 8D, 8E, and 8G are cross-sectional views illustrating some processes of a method of manufacturing an electronic device according to an embodiment of the invention. FIGS. 8B and 8F are plan views illustrating some processes of a method of manufacturing an electronic device according to an embodiment of the invention. A method of manufacturing an electronic device according to an embodiment shown in FIGS. 7 to 8F may be a method of manufacturing the electronic device DD according to an embodiment described above with reference to FIGS. 1 to 6. In an embodiment, a method of manufacturing an electronic device including a protective layer PL disposed under a display panel DP is provided. Hereinafter, in describing a method of manufacturing an electronic device according to an embodiment with reference to FIG. 7 and FIGS. 8A to 8G, components which are the same as the aforementioned components will be given the same reference numerals or symbols and any repetitive detailed descriptions thereof will be omitted.

Referring to FIG. 7, a method of manufacturing an electronic device according to an embodiment includes a process of preparing a display panel and a mask (S100), a process of providing an ink (S200), a process of forming an ink layer (S300), a process of disposing a stamp (S400), a process of forming a preliminary protective layer (S500), and a process of forming a protective layer (S600).

Referring to FIGS. 7 and 8A, FIG. 8A schematically illustrates the process of preparing the display panel, which includes a display region and a non-display region surrounding the display region, and the mask which is disposed on a first lower surface of the display panel (S100), and the process of providing the ink on the first lower surface DP-LF through the mask (S200).

An ink INK may be provided on a lower surface DP-LF of a display panel DP through the mask. In this specification, the lower surface DP-LF of the display panel DP may be referred to as “a first lower surface”. In an embodiment, the ink INK may be disposed directly on the first lower surface DP-LF. Accordingly, no additional adhesive layer may be provided between the display panel DP and the protective layer PL (see FIG. 5) to be formed afterward, and thus the processibility of the electronic device may be improved. The ink INK may be disposed on the mask MK. At least a portion of the ink INK may be provided on a top surface MK-UF of the mask MK. Since at least a portion of the ink INK is provided directly on the top surface MK-UF of the mask MK, a planar area of an ink layer IKL (see FIG. 8B) to be formed afterward may be relatively greater than a planar area of the display panel DP.

The ink INK may include a base resin and a filler dispersed in the base resin. The base resin may include at least one selected from an acrylate-based resin, a urethane-based resin, a fluorine-based resin, an epoxy-based resin, a polyester-based resin, a polyamide-based resin, and a silicone-based resin. As the base resin, an acrylate-based resin, a urethane-based resin, a fluorine-based resin, an epoxy-based resin, a polyester-based resin, a polyamide-based resin, or a silicone-based resin may be provided in the form of a monomer or an oligomer. The base resin included in the ink INK may include a thermosetting resin. The base resin included in the ink INK may be provided in a liquid form before curing. The ink INK may include the filler, and the filler may include at least one selected from a shielding material, a heat-dissipating material, and a supporting material. However, an embodiment of the invention is not limited thereto, and the ink INK may further include an additional additive such as a light-shielding material, or the like.

Referring to FIGS. 7, 8B, and 8C, FIGS. 8B and 8C schematically illustrate the process of forming the ink layer IKL by pressurizing the ink INK with a first squeegee SQ1 to apply the ink INK to the first lower surface DP-LF in a way such that the ink layer IKL overlaps a display region AA and a non-display region NAA (S300). FIG. 8B schematically illustrates a plan view of a display module viewed in the third direction DR3 in the process of forming the ink layer IKL (S300), and FIG. 8C schematically illustrates a cross-sectional view of the display module in the process of forming the ink layer IKL (S300).

The ink layer IKL may be formed by applying the ink INK. The ink INK may be applied to the lower surface DP-LF of the display panel DP through a screen printing method. In an embodiment, the ink INK may be directly applied to the lower surface DP-LF of the display panel DP.

The ink INK may be applied to the lower surface DP-LF of the display panel DP by being pressurized with the first squeegee SQ1. In an embodiment, the first squeegee SQ1 may have a shape extending in the second direction DR2, and the first squeegee SQ1 may move in the first direction DR1. The first squeegee SQ1 may squeeze out the ink INK in the first direction DR1, while moving in the first direction DR1. Since the ink INK is squeezed out by the first squeegee SQ1, the ink INK may be applied to overlap the display region AA and the non-display region NAA. A first length L1 of the first squeegee SQ1 in the second direction DR2 may be greater than a length L3 of the display panel DP in the second direction DR2. Accordingly, a length, in the second direction DR2, of the ink layer IKL formed by the first squeegee SQ1 may be greater than the length L3 of the display panel DP in the second direction DR2. Thus, on a plane, an area of the ink layer IKL may be greater than an area of the display panel DP. Since the first length L1 of the first squeegee SQ1 has a relatively greater value than the length L3 of the display panel DP, the ink INK may be evenly applied on a plan view, and thus the ink layer IKL to be formed may have substantially a constant or uniform thickness, on a plane view.

The ink layer IKL may overlap the display region AA and the non-display region NAA. The ink layer IKL may include a first ink part IKL1 overlapping the display region AA and a second ink part IKL2 overlapping the non-display region NAA. In the process of forming the ink layer IKL, the first ink part IKL1 and the second ink part IKL2 may be formed from a same material through a same process. Accordingly, the first ink part IKL1 and the second ink part IKL2 may have substantially a same thickness value, and the first ink part IKL1 and the second ink part IKL2 may have substantially a same density value. The first ink part IKL1 and the second ink part IKL2 may substantially form one component or integrally formed with each other as a single unitary indivisible part.

Referring to FIGS. 7, 8D, and 8E, FIGS. 8D and 8E schematically illustrate the process of disposing the stamp ST while being spaced at a predetermined distance in one direction with respect to the first lower surface DP-LF in a was such that the stamp ST overlaps the display region AA (S400), and the process of forming the preliminary protective layer P_PL by pressurizing the ink layer IKL with the stamp ST in an opposite direction of the one direction (S500).

The stamp ST may be disposed to overlap the display region AA. The stamp ST may be disposed on the ink layer IKL while being spaced at a predetermined distance in the third direction DR3. The ink layer IKL may be pressurized by the stamp ST in an opposite direction of the third direction DR3. The first ink part IKL1 may be pressurized by the stamp ST, and the second ink part IKL2 may not be pressurized by the stamp ST.

The preliminary protective layer P_PL may be formed by pressurizing the ink layer IKL with by the stamp ST. The preliminary protective layer P_PL may include a first preliminary protective portion P_PL1 overlapping the display region AA and a second preliminary protective portion P_PL2 overlapping the non-display region NAA. The first preliminary protective portion P_PL1 may be formed by pressurizing the first ink part IKL1 with the stamp ST. The second preliminary protective portion P_PL2 may be formed from the second ink part IKL2 on which a pressing process is not performed. The second preliminary protective portion P_PL2 may have substantially a same physical property as the second ink part IKL2. A thickness of the first preliminary protective portion P_PL1 may be less than that of the second preliminary protective portion P_PL2. Since the second preliminary protective portion P_PL2 is not pressurized by the stamp ST and only the process of forming the first preliminary protective portion P_PL1 includes a process of pressing with the stamp ST, a density of the first preliminary protective portion P_PL1 may be greater than a density of the second preliminary protective portion P_PL2, and a thermal conductivity of the first preliminary protective portion P_PL1 may be greater than a thermal conductivity of the second preliminary protective portion P_PL2.

The preliminary protective layer P_PL may be formed by pressurizing a portion of the ink layer IKL with the stamp ST and simultaneously curing the portion of the ink layer IKL. The disposed ink INK (see FIG. 8A) and the applied ink layer IKL may include a curable resin, and the ink layer IKL may be formed by pre-curing or curing the curable resin with the stamp ST. The first preliminary protective layer P_PL1 may be formed by pressurizing and curing the first ink part IKL1 with the stamp ST.

A top surface of the ink layer IKL may be in contact with a lower surface of the stamp ST, and the lower surface of the stamp ST in contact with the ink layer IKL may have a temperature of about 100° C. or higher. In an embodiment, for example, the lower surface of the stamp ST in contact with the ink layer IKL may have a temperature in a range of about 100° C. to about 300° C. Accordingly, the process of pressurizing, by the stamp ST, the ink layer IKL in an opposite direction of the third direction DR3 may include a process of thermally curing at least a portion of the ink layer IKL with the stamp ST. The first preliminary protective portion P_PL1 may be formed by thermally curing the first ink part IKL1 with the stamp ST. Since the first ink part IKL1 is thermally cured, the flatness of the first preliminary protective portion P_PL1 may be improved in the process of forming a protective layer PL to be described later.

Referring to FIGS. 7, 8F, and 8G, FIGS. 8F and 8G schematically illustrate the process of forming the protective layer PL by pressurizing and flattening, with a second squeegee SQ2, a top surface of the preliminary protective layer P_PL which overlaps the display region AA and the non-display region NAA (S600).

The protective layer PL may be formed through the process of pressurizing and flattening the top surface of the preliminary protective layer P_PL with the second squeegee SQ2. The protective layer PL may include a first protective portion PL1 overlapping the display region AA and a second protective portion PL2 overlapping the non-display region NAA. The first protective portion PL1 may be formed by pressurizing and flattening the first preliminary protective portion P_PL1 with the second squeegee SQ2. The second protective portion PL2 may be formed from the second preliminary protective portion P_PL2 on which a pressing process is not performed.

In an embodiment, the second squeegee SQ2 may have a shape extending in the second direction DR2, and the second squeegee SQ2 may move in the first direction DR1. Since the second squeegee SQ2 moves in the first direction DR1, the top surface of the preliminary protective layer P_PL may be squeezed out and flattened by the second squeegee SQ2. The second squeegee SQ2 may move in the display region AA and the non-display region NAA, and the second squeegee SQ2 may perform a function of flattening the respective top surfaces of the first preliminary protective portion P_PL1 overlapping the display region AA and the second preliminary protective portion P_PL2 overlapping the non-display region NAA. The first protective portion PL1 and the second protective portion PL2 thus formed may each have substantially the same thickness.

A second length L2 of the second squeegee SQ2 in the second direction DR2 may be substantially the same as the length of the display panel DP in the second direction DR2. In addition, the second length L2 of the second squeegee SQ2 may be less than the first length L1 (see FIG. 8B) of the aforementioned first squeegee SQ1 (see FIG. 8B).

A electronic device according to an embodiment of the invention may include, under a display panel, a protective layer that performs multiple functions, and thus effects of reducing a thickness of the electronic device and simplifying components may be achieved. Since a display panel includes light emitting elements which cause various side effects, conventional electronic devices include, under the display panel, a plurality of members such as a shielding layer, a heat-dissipating layer, a cushion layer, a supporting layer, or the like in order to alleviate such side effects. In embodiments of the invention, the protective layer which performs the above functions is disposed, such that the protective layer may perform the functions executed by a plurality of typical layers, and also effects of reducing a thickness, simplifying components, and increasing a manufacturing process efficiency may be achieved. The impact resistance of the display panel against an external impact may be increased since the protective layer is disposed under the display panel in the electronic device according to an embodiment of the invention.

In addition, in the electronic device according to an embodiment of the invention, the protective layer includes a first protective portion and a second protective portion having different density values, respectively, and thus the reliability of the electronic device may be improved. In such an embodiment, the first protective portion overlapping a display region is formed through a stamping process during manufacture, whereas the second protective portion overlapping a non-display region does not include the stamping process during manufacture. Since the first protective portion is formed through the stamping process during manufacture, a thermal conductivity of the first protective portion may have a relatively high value. Accordingly, since the electronic device according to an embodiment of the invention includes the first protective portion, a performance capability of a heat-dissipating function for dissipating heat generated from the display panel in the display region may be improved.

Both the process of manufacturing the first protective portion overlapping the display region and the process of manufacturing the second protective portion overlapping the non-display region include a process of flattening with a second squeegee. When the first protective portion overlapping the display region includes a stamping process during manufacture, the reliability of the electronic device may deteriorate since a thickness of the first protective portion is different from a thickness of the second protective portion. However, since the method of manufacturing an electronic device according to an embodiment of the invention includes the flattening process, the thickness of the protective layer may be formed evenly in the entire region including the display region and the non-display region, and thus the reliability of the electronic device may be improved.

According to an embodiment of the invention, when a protective layer is disposed under a display panel in an electronic device, the densities of portions respectively overlapping a display region and a non-display region are different from each other, such that the flatness of the protective layer may be improved and also heat generated from the display panel may be effectively dissipated, thereby improving the reliability of the electronic device.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. An electronic device comprising:
a display panel including a display region and a non-display region surrounding at least a portion of the display region; and
a protective layer disposed under the display panel,
wherein the protective layer includes a first protective portion overlapping the display region and having a first density, and a second protective portion overlapping the non-display region and having a second density, and
the first density is greater than the second density.

2. The electronic device of claim 1, wherein a thermal conductivity of the first protective portion is different from a thermal conductivity of the second protective portion.

3. The electronic device of claim 2, wherein the thermal conductivity of the first protective portion is in a range of about 70 W/mK to about 200 W/mK.

4. The electronic device of claim 1, wherein the first protective portion comprises a first base resin, and a first filler dispersed in the first base resin, and
the second protective portion comprises a second base resin, and a second filler dispersed in the second base resin.

5. The electronic device of claim 4, wherein a weight ratio of the first filler to a total weight of the first protective portion is greater than a weight ratio of the second filler to a total weight of the second protective portion.

6. The electronic device of claim 4, wherein materials of the first base resin and the second base resin are the same as each other, and materials of the first filler and the second filler are the same as each other.

7. The electronic device of claim 4, wherein an average diameter of each of the first filler and the second filler is in a range of about 5 μm to about 100 μm.

8. The electronic device of claim 1, wherein the protective layer is disposed directly on a lower surface of the display panel.

9. The electronic device of claim 1, wherein a thickness of the first protective portion and a thickness of the second protective portion are each in a range of about 50 μm to about 300 μm.

10. The electronic device of claim 1, wherein a thickness of the first protective portion and a thickness of the second protective portion are substantially the same as each other.

11. A method of manufacturing an electronic device, the method comprising:
preparing a display panel including a display region and a non-display region surrounding the display region, and a mask disposed on a first lower surface of the display panel;
providing an ink on the first lower surface;
forming an ink layer by pressurizing the ink with a first squeegee to apply the ink to the first lower surface in a way such that the ink layer overlaps the display region and the non-display region;
disposing a stamp while being spaced at a distance in one direction with respect to the first lower surface, in a way such that the stamp overlaps the display region and does not overlap the non-display region;
forming a preliminary protective layer by pressurizing a portion of the ink layer overlapping the display region with the stamp in an opposite direction of the one direction; and
forming a protective layer by pressurizing and flattening, with a second squeegee, a top surface of the preliminary protective layer which overlaps the display region and the non-display region.

12. The method of claim 11, wherein the ink layer comprises a first ink part overlapping the display region and a second ink part overlapping the non-display region, and
a density of the first ink part is substantially the same as a density of the second ink part.

13. The method of claim 11, wherein the preliminary protective layer comprises a first preliminary protective portion overlapping the display region and a second preliminary protective portion overlapping the non-display region, and
a thickness of the first preliminary protective portion is less than a thickness of the second preliminary protective portion.

14. The method of claim 11, wherein the protective layer comprises a first protective portion overlapping the display region and a second protective portion overlapping the non-display region, and
a first density of the first protective portion is greater than a second density of the second protective portion.

15. The method of claim 11, wherein in the pressurizing the ink with the first squeegee to apply the ink to the first lower surface, the first squeegee moves in a first direction, and
a first length of the first squeegee in a second direction crossing the first direction on a plane is greater than a second length of the second squeegee in the second direction.

16. The method of claim 15, wherein the first length is greater than a third length of the display panel in the second direction, and
the second length is substantially the same as the third length.

17. The method of claim 11, wherein the ink is in contact with at least a portion of a top surface of the mask.

18. The method of claim 11, wherein the ink includes a curable resin, and
the forming the preliminary protective layer comprises thermally curing the curable resin included in the ink.

19. The method of claim 18, wherein the preliminary protective layer comprises a first preliminary protective portion overlapping the display region and a second preliminary protective portion overlapping the non-display region, and
the forming the preliminary protective layer comprises thermally curing the first preliminary protective portion.

20. The method of claim 18, wherein in the forming the preliminary protective layer, one surface of the stamp is in contact with one surface of the ink layer, and
the one surface of the stamp has a temperature of about 100° C. or higher.
